(19) United States
(12) Patent Application Publication
(10) Pub. No.: US 2026/0230694 A1
(43) Pub. Date: Aug. 6, 2026

(54) LIGHT OUTPUT DEVICE, AND CAMERA DEVICE AND SENSOR MODULE COMPRISING SAME

(71) Applicant: LG INNOTEK CO., LTD., Seoul (KR)

(72) Inventors: Sung Ki KIM, Seoul (KR); Jong Sub LEE, Seoul (KR); Phil Jun JEON, Seoul (KR)

(21) Appl. No.: 19/150,296

(22) PCT Filed: Jan. 31, 2024
(86) PCT No.: PCT/KR2024/001465

§ 371 Date: Jul. 23, 2025

(30) Foreign Application Priority Data
Feb. 3, 2023 (KR) 10-2023-0014798
Feb. 8, 2023 (KR) 10-2023-0016733

(51) Int. Cl. H04N 23/55; G01J 1/04; G01J 1/08; H04N 23/56

(52) U.S. Cl. CPC H04N 23/55; G01J 1/0411; G01J 1/08; H04N 23/56

(57) ABSTRACT

A light output device according to one embodiment of the present invention comprises: one vertical cavity surface emission laser (VCSEL) including a plurality of emitters in an array and including a first area and a second area that are isolated from each other; a lens disposed on the first area and the second area and overlapping both the first area and the second area in an optical axis direction; a light conversion member disposed between the first area and the lens to defocus or scatter an output light signal output from the first area; and one drive IC that independently drives the emitters of the first area and the emitters of the second area, wherein the output light signal output from the first area is emitted as a surface illumination pattern, the output light signal output from the second area is emitted in a dot illumination pattern, and the second area directly faces the lens in the optical axis direction.

### TECHNICAL FIELD

The present invention relates to a light output device and a camera device including the same. Additionally, the present invention relates to a sensor module.

### BACKGROUND ART

3D content is being applied in many fields such as education, manufacturing, and autonomous driving as well as games and culture, and depth information (depth map) is required to obtain 3D content. Depth information is information that represents distance in space, and represents perspective information of another point for one point in a two-dimensional image. Methods for obtaining the depth information include a method of projecting infrared (IR) structured light onto an object, a method using a stereo camera, and a time of flight (TOF) method.

According to the ToF method, the distance to an object is calculated by measuring the time of flight, that is, the time it takes for light to be emitted and reflected. The biggest advantage of the ToF method is that it quickly provides distance information about a three-dimensional space in real time. Additionally, users may obtain accurate distance information without having to apply separate algorithms or perform hardware corrections. Also, accurate depth information may be obtained even when measuring very close subjects or moving subjects.

According to the IR structured light method, a point illumination pattern, which is structured light, may be emitted from a light emitting unit, and according to the ToF method, a surface illumination pattern may be emitted from a light emitting unit. There may be different situations where depth information acquisition according to the IR structured light method is more appropriate and situations where depth information acquisition according to the ToF method is more appropriate.

Alternatively, in the ToF method, a surface illumination pattern may be output for high resolution. However, a limit is placed on the total average power (total Pavg) of the light output to satisfy eye safety standards. Accordingly, there is a problem that it is difficult to use the surface illumination pattern when attempting to obtain long-distance depth information. To solve these problems, there are attempts to use a point illumination pattern when attempting to obtain long-distance depth information, and a surface illumination pattern when attempting to obtain short-distance depth information.

Therefore, a technology in which a single camera device is designed to output both a surface illumination pattern and a point illumination pattern is needed. However, when a single camera device includes both a flood illuminator that outputs a surface illumination pattern and a dot projector that outputs a point illumination pattern, there is a problem that the size of the device increases. In addition, in order for the flood illuminator to implement a surface illumination pattern and the dot projector to implement a point illumination pattern, heights of the flood illuminator and the dot projector need to be designed to be different, and a separate structure is required for this.

In addition, infrared sensors and visible light sensors used for 3D sensing, such as conventional structured light sensors and dToF, sense infrared and visible light using their own optical systems. In this case, the paths of light incident on the infrared sensor and the visible light sensor are distinguished, and a plurality of holes for light to be incident are required. When holes are disposed in a display, the holes may not be disposed in the display depending on an area where the holes are disposed. Therefore, conventional sensor modules have a problem in that the area required to dispose the holes in the display is large. A solution is needed to reduce the area of the holes in these displays.

### DISCLOSURE

### Technical Problem

The technical problem to be achieved by the present invention is to provide a light output device that integrates a flood illuminator that outputs a surface illumination pattern and a dot projector that outputs a point illumination pattern.

Another technical problem to be achieved by the present invention is to provide a camera device capable of measuring depth information not only at a short distance but also at a long distance.

Still another technical problem to be achieved by the present invention is to provide a camera device that supports both an IR structured light method and a ToF method.

Yet another technical problem to be achieved by the present invention is to provide a sensor module capable of reducing an area of a hole in a display.

Yet another technical problem to be achieved by the present invention is to provide a sensor module in which the number of holes is reduced to 1.

The problems to be solved by the embodiments are not limited thereto, and purposes or effects which may be grasped from solutions or embodiments of the problems to be described below are also included.

### Technical Solution

A light output device according to one embodiment of the present invention includes one vertical cavity surface emission laser (VCSEL) including a plurality of emitters in an array form and including a first region and a second region that are isolated from each other, a lens disposed on the first region and the second region and overlapping both the first region and the second region in an optical axis direction, a light conversion member disposed between the first region and the lens to defocus or scatter an output light signal output from the first region, and one driving IC configured to independently drive an emitter of the first region and an emitter of the second region, wherein the output light signal output from the first region is emitted in a surface illumination pattern, and an output light signal output from the second region is emitted in a point illumination pattern, and the second region directly faces the lens in the optical axis direction.

The light conversion member may be a layer including a microlens array protruding toward the lens or an etched surface protruding toward the lens.

A vertical distance between the first region and an upper surface of the light conversion member may be shorter than a vertical distance between the upper surface of the light conversion member and the lens.

The light conversion member may be disposed to be in direct contact with the first region.

The one VCSEL may be disposed on a board on which the one driving IC is disposed, and a height of the first region and a height of the second region may be the same based on the board.

The light conversion member may not be disposed between the second region and the lens.

When viewed from above, an area of the second region may be greater than an area of the first region.

The second region may be disposed in a region including a center of the one VCSEL, and the first region may be disposed in an edge region of the one VCSEL.

The second region may be disposed in a region including a center of the one VCSEL, and the first region may be disposed to surround at least a portion of the second region.

A diffractive optical element (DOE) pattern may be formed along an edge region of an upper surface of the lens.

The DOE pattern may be formed symmetrically with respect to a center of the one VCSEL.

A light output device according to another embodiment of the present invention includes a plurality of emitters in an array form, one vertical cavity surface emission laser (VCSEL) including a first region and a second region that are isolated from each other, a lens disposed on the first region and the second region and overlapping both the first region and the second region in an optical axis direction, and one driving IC independently driving an emitter of the first region and an emitter of the second region, wherein the second region is disposed in a region including a center of the one VCSEL, the first region is disposed to surround at least a portion of the second region, a diffractive optical element (DOE) pattern is formed along an edge region of an upper surface of the lens, an output light signal output from the first region is emitted in a surface illumination pattern, and an output light signal output from the second region is emitted in a point illumination pattern.

A camera device according to one embodiment of the present invention includes a light emitting unit which generates an output light signal and irradiates an object with the output light signal, a light receiving unit which receives an input light signal reflected from the object and then input, and an information generation unit which generates depth information of the object using the input light signal input to the light receiving unit, wherein the light emitting unit includes a plurality of emitters in an array form, one vertical cavity surface emission laser (VCSEL) including a first region and a second region that are isolated from each other, a lens which is commonly disposed on the first region and the second region, a light conversion member which is disposed between the first region and the lens and defocuses or scatters an output light signal output from the first region, and one driving IC which independently drives the first region and the second region, wherein the output light signal output from the first region is emitted in a surface illumination pattern, and an output light signal output from the second region is emitted in a point illumination pattern.

A sensor module according to an embodiment includes a lens unit that refracts incident light to output first incident light and second incident light having different wavelengths, a transmissive portion that transmits the first incident light and the second incident light, a reflective portion which is disposed in the transmissive portion, transmits the first incident light, and reflects the second incident light, and a first light receiving unit that receives the first incident light and a second light receiving unit that receives the second incident light, wherein the second incident light may be reflected by the reflective portion and reach the second light receiving unit.

The first light receiving unit may be disposed spaced apart from the lens unit on the same axis in a first direction in which the first incident light is incident, and the first light receiving unit and the second light receiving unit may be disposed spaced apart in a second direction perpendicular to the first direction while being parallel to each other.

The lens unit may refract the first incident light to be focused on the first light receiving unit and refract the second incident light to be focused on the second light receiving unit.

The transmissive portion may be disposed between the lens unit and the first light receiving unit and the second light receiving unit.

The transmissive portion may have a cylindrical or polygonal cylindrical shape, and the reflective portion may be formed in a manner in which a reflective material is coated or attached in the transmissive portion.

The reflective portion may include a first reflective surface and a second reflective surface, and the first reflective surface and the second reflective surface may be disposed parallel to each other so as to face each other.

The first reflective surface may be disposed between the lens unit and the first light receiving unit to have a predetermined angle with respect to the second direction.

The second reflective surface may be spaced apart from the second light receiving unit in the first direction and disposed to have a predetermined angle with respect to the second direction.

The first reflective surface and the second reflective surface may be disposed to have an angle greater than 0° and less than or equal to 45° with respect to the second direction.

The transmissive portion may include a first surface, a second surface facing the first surface, and a third surface disposed between the first surface and the second surface, wherein the first surface and the second surface may be parallel to the lens unit or the first light receiving unit, and the third surface may be perpendicular to the first surface and the second surface.

A sum of a vertical distance between one point on the first reflective surface and the second surface and a vertical distance between one point on the second reflective surface and the second surface may be 0.8 to 1.2 times a height of the third surface in the first direction, and one point on the first reflective surface may be at a first distance from an end of the first reflective surface in a direction toward the second reflective surface, and one point on the second reflective surface may be at the first distance from an end of the second reflective surface in a direction toward the first reflective surface.

A shortest horizontal distance between one point on the first reflective surface and the third surface may be 0.9 to 1.1 times a shortest horizontal distance between one point on the second reflective surface and the third surface, and one point on the first reflective surface may be at a first distance from an end of the first reflective surface in a direction toward the second reflective surface, and one point on the second reflective surface may be at the first distance from an end of the second reflective surface in a direction toward the first reflective surface.

The first incident light or the second incident light passing through the lens unit may be incident on the first surface and emitted to the second surface to be incident on the first light receiving unit or the second light receiving unit.

A sensor module according to the embodiment may include an opening for allowing the first incident light and the second incident light to enter the lens unit, and a frame for accommodating the lens unit, the transmissive portion, the reflective portion, and the first and second light receiving units; wherein the lens unit may be disposed in the opening.

The opening may be disposed spaced apart from the first light receiving portion in the first direction on the same axis.

A width of the opening in the second direction may be 1 time or more and 2 times or less a width of the lens unit in the second direction.

The first incident light may be visible light, the second incident light may be infrared light, the first light receiving unit may be a visible light recognition sensor, and the second light receiving unit may be an infrared recognition sensor.

The transmissive portion may be a prism, and the reflective portion may be a dichroic filter.

A mobile device according to an embodiment includes a display including a hole, and a sensor module disposed at the bottom of the display, wherein the sensor module includes a lens unit which refracts incident light passing through the hole to output first incident light and second incident light having different wavelengths, a transmissive portion which transmits the first incident light and the second incident light, a reflective portion which is disposed in the transmissive portion, transmits the first incident light, and reflects the second incident light, and a first light receiving unit which receives the first incident light and a second light receiving unit which receives the second incident light, wherein the hole, the lens unit, and the first light receiving unit may overlap in an optical axis direction of the lens unit.

### Advantageous Effects

According to an embodiment of the present invention, a camera device capable of implementing both a point illumination pattern and a surface illumination pattern can be obtained without increasing the complexity of a manufacturing process and the size of a device.

In addition, according to the embodiment of the present invention, a sensor module capable of reducing the area of a hole in a display can be provided.

In addition, according to the embodiment of the present invention, a sensor module in which the number of holes is reduced to 1 can be provided.

Various useful advantages and effects of the present invention are not limited to the above-described contents, and can be more easily understood in a process of describing specific embodiments of the present invention.

### DESCRIPTION OF DRAWINGS

FIG. 1 is a block diagram of a camera device according to one embodiment of the present invention.

FIG. 2 is a conceptual cross-sectional view of the camera device according to one embodiment of the present invention.

FIG. 3 (a) and (b) are examples of a light-emitting pattern of the camera device according to one embodiment of the present invention.

FIG. 4 is a top view of a light output device according to one embodiment of the present invention.

FIG. 5 is a cross-sectional view of the light output device according to one embodiment of the present invention.

FIG. 6 is a top view of a light conversion member in the light output device according to one embodiment of the present invention.

FIG. 7 is a cross-sectional view of a light output device according to another embodiment of the present invention.

FIG. 8 is a top view of a light conversion member in the light output device according to another embodiment of the present invention.

FIG. 9 is a top view of a light output device according to still another embodiment of the present invention.

FIG. 10 is a cross-sectional view of the light output device according to still another embodiment of the present invention.

FIG. 11 is an example of an upper surface of a lens of the light output device according to still another embodiment of the present invention.

FIG. 12 is an exploded view of a camera device according to an embodiment of the present invention.

FIG. 13 is a cross-sectional view of a conventional sensor module.

FIG. 14 is a configuration diagram of a sensor module according to an embodiment.

FIG. 15 is a cross-sectional view of the sensor module according to the embodiment.

FIG. 16 is a cross-sectional view of a transmissive portion of the sensor module according to the embodiment.

### MODES OF THE INVENTION

Hereinafter, preferred embodiments of the present invention will be described in detail with reference to the attached drawings.

However, the technical idea of the present invention is not limited to some of the embodiments described, but can be implemented in various different forms, and within the scope of the technical idea of the present invention, one or more of the components among the embodiments can be selectively combined or substituted and used.

In addition, terms (including technical and scientific terms) used in the embodiments of the present invention can be interpreted as having a meaning that can be generally understood by a person of ordinary skill in the technical field to which the present invention belongs, unless explicitly and specifically defined and described, and terms that are commonly used, such as terms defined in a dictionary, can be interpreted in consideration of the contextual meaning of the relevant technology.

Additionally, the terms used in the embodiments of the present invention are for the purpose of describing the embodiments and are not intended to limit the present invention.

In this specification, the singular may also include the plural unless specifically stated otherwise in the phrase, and when it is described as “at least one (or one or more) of A, B, and C,” it may include one or more of all combinations in which A, B, and C can be combined.

Additionally, in describing components of embodiments of the present invention, terms such as first, second, A, B, (a), (b), etc. may be used.

These terms are only intended to distinguish one component from another, and the nature, order, sequence, etc. of the component are not limited by these terms.

Further, when a certain component is described as being ‘connected,’ ‘coupled,’ or ‘joined’ to another component, it may include not only cases where the component is directly connected, coupled, or joined to the other component, but also cases where the component is ‘connected,’ ‘coupled,’ or ‘joined’ by still another component between the component and the other component.

Additionally, when one component is described as being formed or disposed “above (upper) or below (lower)” another component, above (upper) or below (lower) includes not only cases where the two components are in direct contact with each other, but also cases where one or more still other components are formed or disposed between the two components. Additionally, when expressed as “above (upper) or below (lower),” it may include the meaning of not only the upward direction but also the downward direction based on one component.

A camera device according to an embodiment of the present invention may mean a camera that extracts depth information using a time of flight (ToF) function. Therefore, the camera device may be used interchangeably with a depth information extraction device, a ToF camera device, a ToF camera module, a ToF camera, etc.

Alternatively, the camera device according to the embodiment of the present invention may mean a camera that supports both a ToF method and an IR structured light function and extracts depth information.

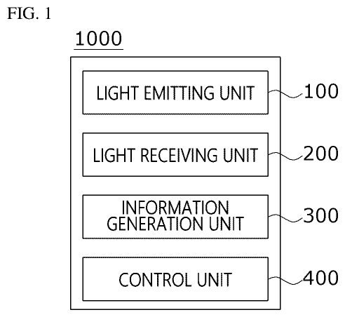

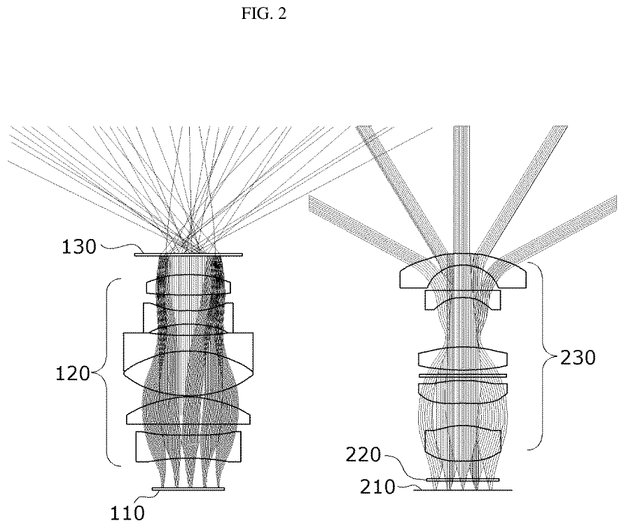

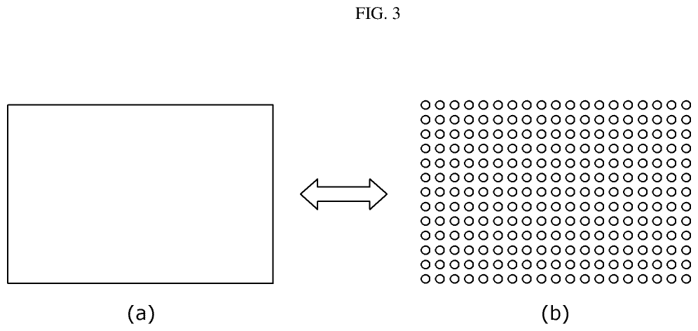

FIG. 1 is a block diagram of a camera device according to one embodiment of the present invention, FIG. 2 is a conceptual cross-sectional view of the camera device according to one embodiment of the present invention, and FIG. 3 is an example of a light-emitting pattern of the camera device according to one embodiment of the present invention.

Referring to FIGS. 1 and 2, a camera device 1000 according to an embodiment of the present invention may include a light emitting unit 100, a light receiving unit 200, an information generation unit 300, and a control unit 400.

The light emitting unit 100 may generate and output an output light signal in the form of a pulse wave or continuous wave. The continuous wave may be in the form of a sinusoidal wave or square wave. By generating the output light signal in the form of a pulse wave or continuous wave, the camera device 1000 may detect a time difference or phase difference between an output light signal output from the light emitting unit 100 and an input light signal reflected from an object and then input to the light receiving unit 200. In this specification, output light may refer to light that is output from the light emitting unit 100 and is incident on an object, and input light may refer to light that is output from the light emitting unit 100, reaches an object, is reflected from the object, and is input to the light receiving unit 200. In this specification, a pattern of the output light may be referred to as an emission pattern, and a pattern of the input light may be referred to as an incident pattern. From an object's point of view, the output light may be incident light, and the input light may be reflected light.

The light emitting unit 100 may include a light source 110 and a lens group 120 disposed on the light source 110. The light source 110 generates and outputs light. The light generated by the light source 110 may be infrared light having a wavelength of 770 to 3000 nm. Alternatively, the light generated by the light source 110 may be visible light having a wavelength of 380 to 770 nm. The light source 110 may use a light emitting diode (LED) and may have a form in which a plurality of light emitting diodes are arranged in a certain pattern. In addition, the light source 110 may include an organic light emitting diode (OLED) or a laser diode (LD). Alternatively, the light source 110 may be a vertical cavity surface emitting laser (VCSEL). A VCSEL is one type of laser diode that may convert an electrical signal into an optical signal and output a wavelength of about 800 to 1000 nm, for example, about 850 nm or about 940 nm. The light source 110 may generate an output light signal in the form of a pulse wave or continuous wave by repeatedly flashing (on/off) at a regular time interval. The time interval may be the frequency of an output light signal.

The lens group 120 may condense light output from the light source 110 and output the condensed light to the outside. The lens group 120 may be disposed above the light source 110 and spaced apart from the light source 110. Here, the side above the light source 110 may mean a side to which light is output from the light source 110. The lens group 120 may include at least one lens. When the lens group 120 includes a plurality of lenses, the lenses may be aligned with respect to a central axis to form an optical system. Here, the central axis may be the same as an optical axis of the optical system. According to the embodiment of the present invention, the lens group 120 may include a collimation lens.

A cover member 130 may be additionally disposed above the lens group 120. Although not shown, a diffusion member may be additionally disposed between the lens group 120 and the cover member 130 so that light output from the light source 110 and the lens group 120 is refracted or diffracted and output.

The light receiving unit 200 may receive an optical signal reflected from an object. In this case, the received optical signal may be an optical signal output by the light emitting unit 100 and reflected from the object.

The light receiving unit 200 may include an image sensor 210, a filter 220 disposed on the image sensor 210, and a lens group 230 disposed on the filter 220. A light signal reflected from the object may pass through the lens group 230. An optical axis of the lens group 230 may be aligned with an optical axis of the image sensor 210. The filter 220 may be disposed between the lens group 230 and the image sensor 210. The filter 220 may be disposed on an optical path between the object and the image sensor 210. The filter 220 may filter light having a predetermined wavelength range. Light of a specific wavelength band may be transmitted through the filter 220. The filter 220 may transmit light of a specific wavelength. For example, the filter 220 may transmit light in the infrared band and block light outside the infrared band. The image sensor 210 may sense light. The image sensor 210 may receive an optical signal. The image sensor 210 may detect an optical signal and output the optical signal as an electrical signal. The image sensor 210 may detect light having a wavelength corresponding to the wavelength of light output by the light source 110. For example, the image sensor 210 may detect light in the infrared band.

The image sensor 210 may be configured to have a structure in which a plurality of pixels are arranged in a grid pattern. The image sensor 210 may be a complementary metal oxide semiconductor (CMOS) image sensor or may be a charge coupled device (CCD) image sensor.

When the camera device 1000 according to the embodiment of the present invention supports the ToF method, the image sensor 210 may include a ToF sensor that receives IR light reflected from an object and measures a distance using a time difference or a phase difference. When the camera device 1000 according to the embodiment of the present invention supports both the ToF method and the IR structured light method, the image sensor 210 may include a ToF sensor for receiving IR light reflected from an object and measuring a distance using a time difference or a phase difference, and an IR structured light sensor for measuring a distance using a disparity of the IR structured light.

The light receiving unit 200 and the light emitting unit 100 may be disposed side by side. The light receiving unit 200 may be disposed next to the light emitting unit 100. The light receiving unit 200 may be disposed in the same direction as the light emitting unit 100.

The information generation unit 300 may generate depth information of an object using an input light signal input to the light receiving unit 200. For example, the information generation unit 300 may calculate depth information of an object by using the flight time taken for an output light signal output from the light emitting unit 100 to be reflected from the object and then input to the light receiving unit 200. For example, the information generation unit 300 may calculate a time difference between the output light signal and the input light signal using the electrical signal received by the image sensor 210, and calculate a distance between the object and the 3D sensing device 1000 using the calculated time difference. For example, the information generation unit 300 may calculate a phase difference between the output light signal and the input light signal using the electrical signal received from the sensor, and calculate a distance between the object and the camera device 1000 using the calculated phase difference. Alternatively, the information generation unit 300 may calculate a distance between the object and the camera device 1000 by using a disparity between the IR structured light of the output light signal output from the light emitting unit 100 and the IR structured light of the input light signal incident on the light receiving unit 200.

The control unit 400 may control the operation of the light emitting unit 100, the light receiving unit 200, and the information generation unit 300. The information generation unit 300 and the control unit 400 may be implemented in the form of a printed circuit board (PCB). Additionally, the information generation unit 300 and the control unit 400 may be implemented in the form of other configurations. Alternatively, the control unit 400 may also be included in a terminal or vehicle in which the camera device 1000 according to the embodiment of the present invention is disposed. For example, the control unit 400 may be implemented in the form of an application processor (AP) of a smartphone on which the camera device 1000 according to the embodiment of the present invention is mounted, or may be implemented in the form of an electronic control unit (ECU) of a vehicle on which the camera device 1000 according to the embodiment of the present invention is mounted.

According to the embodiment of the present invention, the light emitting unit 100 may output light of various patterns.

For example, the light emitting unit 100 may output a surface illumination pattern (refer to FIG. 3A). The surface illumination pattern may be a form in which light is evenly spread in a certain area, and may be used interchangeably with a flood illumination pattern, a surface light source pattern, etc. Here, evenness does not mean that the space where light is irradiated is irradiated with the same amount of light, but may mean that the light is continuously spread across the space. In the case of the flood illumination pattern, since light is spread evenly (continuously) in space, there is an advantage in obtaining high-resolution depth information when irradiating an object with light of the flood illumination pattern. However, since light is spread evenly in space, an amount of light received is small, and thus the precision of depth information may decrease as a distance to the object increases. Although an output of the light source 110 may be increased to increase precision, this may increase power consumption and cause eye-safety problems.

As another example, the light emitting unit 100 may output a point illumination pattern (refer to FIG. 3B). The point illumination pattern may refer to an array of spots spaced at regular intervals within a predetermined region, and may be used interchangeably with a spot illumination pattern, a point light source pattern, etc. Here, the point illumination pattern may mean a pattern in which light is locally condensed in space, that is, a pattern in which light is not spread continuously in space but is locally concentrated. In the case of the point illumination pattern, since light is concentrated locally, each spot has a high amount of light. Accordingly, there is an advantage in that high-precision depth information may be obtained even when the distance to the object is long. However, since light is locally concentrated, there is a problem that the resolution of depth information is lower than that of the surface illumination pattern.

According to the embodiment of the present invention, the light emitting unit 100 may irradiate an object with light of the surface illumination pattern or light of the point illumination pattern according to a control signal to maximize each advantage.

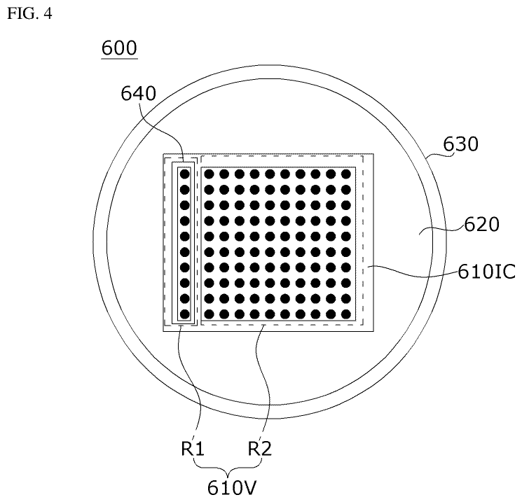

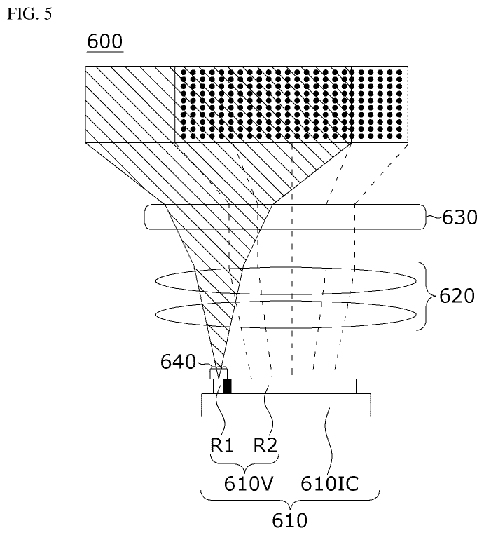

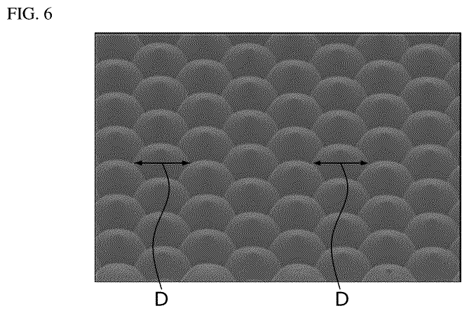

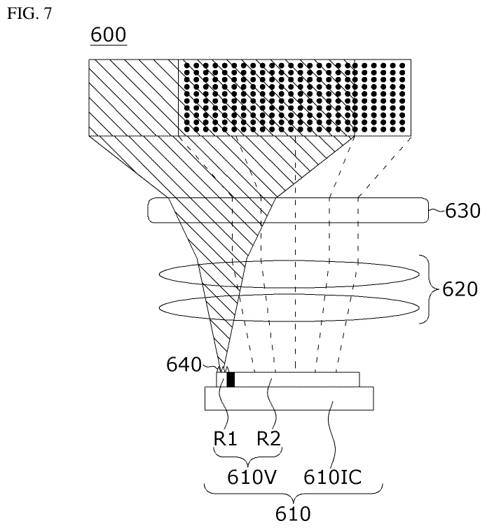

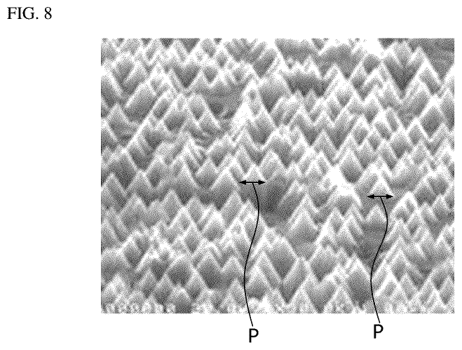

FIG. 4 is a top view of the light output device according to one embodiment of the present invention, FIG. 5 is a cross-sectional view of the light output device according to one embodiment of the present invention, FIG. 6 is a top view of a light conversion member in the light output device according to one embodiment of the present invention, FIG. 7 is a cross-sectional view of a light output device according to another embodiment of the present invention, and FIG. 8 is a top view of a light conversion member in the light output device according to another embodiment of the present invention. In this specification, the light output device may be used interchangeably with the light emitting unit. The description of the light emitting unit with reference to FIGS. 1 to 3 may be applied to the light output device, and for the convenience of explanation, duplicate descriptions of the same content are omitted.

Referring to FIGS. 4 to 8, a light output device 600 may include a light source 610, a lens group 620 disposed on the light source 610, and a cover member 630 disposed on the lens group 620.

The light source 610 may be a vertical cavity surface emitting laser (VCSEL). A VCSEL is one type of laser diode that may convert an electrical signal into an optical signal and output a wavelength of about 800 to 1000 nm, for example, about 850 nm or about 940 nm.

According to the embodiment of the present invention, the light source 610 may include a plurality of emitters in an array form and include one VCSEL 610V including a first region R1 and a second region R2 that are isolated from each other, and an emitter of the first region R1 and an emitter of the second region R2 may be independently driven by one driving integrated chip (IC) 610IC. That is, each of the first region R1 and the second region R2 may have an array form including a plurality of emitters, may be spaced apart from each other, may be implemented on one driving IC 610IC, and may be independently driven by one driving IC 610IC. In this case, a separation distance between the first region R1 and the second region R2 may be 10 μm to 100 μm, preferably 20 μm to 80 μm, and more preferably 30 μm to 60 μm. Accordingly, the size of the light output device 600 may be reduced while the first region R1 and the second region R2 are isolated from each other. When the first region R1 and the second region R2 are independently driven by one driving IC 610IC, fast switching is possible.

According to the embodiment of the present invention, the lens group 620 may be commonly disposed on the first region R1 and the second region R2. That is, the lens group 620 may be disposed on the first region R1 and the second region R2 and may overlap both the first region R1 and the second region R2 in an optical axis direction. That is, as illustrated in FIG. 4, a width of at least one lens included in the lens group 620 may be greater than the sum of a width of the first region R1 and a width of the second region R2, and one lens may be disposed to cover both the first region R1 and the second region R2. Here, the width may mean a length in a direction perpendicular to an optical axis of the light output device 600. The second region R2 may be disposed to directly face the lens group 620 in the optical axis direction. Accordingly, an alignment process between the light source 610 and the lens group 620 may be simplified, the size of the light output device 600 may be minimized, and the structure of the light output device 600 may be simplified.

According to the embodiment of the present invention, an output light signal output from the first region R1 may be emitted in a surface illumination pattern, and an output light signal output from the second region R2 may emitted in a point illumination pattern. To this end, a light conversion member 640 that defocuses or scatters the output light signal output from the first region R1 may be further disposed between the first region R1 and the lens group 620. This light conversion member 640 may be disposed between the first region R1 and the lens group 620, but may not be disposed between the second region R2 and the lens group 620. Accordingly, the output light signal output from the first region R1 may be defocused or scattered by the light conversion member 640 and may be emitted in a surface illumination pattern, and the output light signal output from the second region R2 may not be defocused or scattered and may be emitted in a point illumination pattern.

Accordingly, one VCSEL 610V may be disposed on a board on which one driver IC 610IC is disposed, and a height of the first region R1 and a height of the second region R2 may be the same based on the board. Here, the height of the first region R1 and the height of the second region R2 may each mean the maximum height in a direction toward the optical axis based on the board. The fact that the height of the first region R1 and the height of the second region R2 are the same may mean that the heights are within a margin of error of ±5%. Accordingly, since the output light signal output from the first region R1 is emitted in a surface illumination pattern, the output light signal output from the second region R2 is emitted in a point illumination pattern, and a separate structure for adjusting the heights of the first region R1 and the second region R2 is not required, the size of the light output device 600 may be reduced, and a process of manufacturing the light output device 600 may be simplified.

Referring to FIGS. 5 and 6, the light conversion member 640 may include a microlens array. In this case, the microlens array may protrude in a direction toward the lens group 620. When the output light signal output from the first region R1 passes through the microlens array, it may be defocused and emitted in a surface illumination pattern. According to the embodiment of the present invention, an angle of view of a surface illumination pattern emitted from the first region R1 may be controlled by a pitch or curvature of the microlenses included in the microlens array. Accordingly, even when the area of the first region R1 is designed to be small, the angle of view of the surface illumination pattern emitted from the first region R1 may be expanded by controlling the pitch or curvature of the microlenses included in the microlens array.

According to an embodiment of the present invention, diameters D of the microlenses included in the microlens array may all be designed to be different from each other. For example, the diameters of the microlenses included in the microlens array may be designed randomly. For example, the diameters of the microlenses included in the microlens array may be designed by random number generation. For this purpose, the diameters of the microlenses may be extracted by rejection sampling as many times as the number of microlenses. Accordingly, diffraction angles for each diffraction order may not overlap, constructive interference and destructive interference due to the overlapping of diffraction angles for each diffraction order may be minimized, and a more uniform surface illumination pattern may be implemented.

Alternatively, referring to FIGS. 7 and 8, the light conversion member 640 may be a layer including an etched surface. In this case, the etched surface may protrude in the direction toward the lens group 620. When the output light signal output from the first region R1 passes through the etched surface, it may be scattered and emitted in a surface illumination pattern. According to the embodiment of the present invention, the angle of view of the surface illumination pattern emitted from the first region R1 may be controlled by the surface roughness of the etched surface. Accordingly, even when the area of the first region R1 is designed to be small, the angle of view of the surface illumination pattern emitted from the first region R1 may be expanded by controlling the surface roughness of the etched surface.

According to the embodiment of the present invention, the height and width of the pitch included in the etched surface may both be designed to be different from each other. For example, at least one of the height and width of the pitch included in the etched surface may be designed randomly. For example, at least one of the height and width of the pitch included in the etched surface may be designed by random number generation. For this purpose, at least one of the height and width of the pitch included in the etched surface may be extracted by rejection sampling as many times as the number of pitches. Accordingly, diffraction angles for each diffraction order may not overlap, constructive interference and destructive interference due to the overlapping of diffraction angles for each diffraction order may be minimized, and a more uniform surface illumination pattern may be implemented.

As illustrated in FIGS. 5 and 7, according to the embodiment of the present invention, a vertical distance between the first region R1 and an upper surface of the light conversion member 640 may be shorter than a vertical distance between the upper surface of the light conversion member 640 and the lens group 620. Accordingly, the defocusing or scattering effect of the output light signal output from the first region R1 may be increased. Preferably, the light conversion member 640 may be in contact with the first region R1. Accordingly, the defocusing or scattering effect of the output light signal output from the first region R1 may be maximized.

According to the embodiment of the present invention, when viewed from above, an area of the second region R2 may be larger than an area of the first region R1. Accordingly, the magnitude of power allocated to the point illumination pattern for acquiring long-distance depth information may be ensured to be larger than the magnitude of power allocated to the surface illumination pattern for acquiring short-distance depth information. In addition, as described above, since the angle of view of the surface illumination pattern emitted from the first region R1 may be expanded by controlling the diameters of the microlenses included in the microlens array disposed in the first region R1 or the surface roughness of the etched surface, even when the area of the first region R1 is smaller than that of the second region R2, the surface illumination pattern emitted from the first region R1 may be radiated to the entire irradiation area including the object. Accordingly, a camera device capable of extracting depth information with high precision not only at a short distance but also at a long distance may be obtained. Alternatively, a camera device capable of performing depth information extraction according to the ToF method as well as depth information extraction according to the IR structured light method may be obtained.

In this case, the second region R2 may be disposed in a region including a center of one VCSEL 610V, and the first region R1 may be disposed in an edge region of one VCSEL 610V. Although FIG. 4 illustrates that the first region R1 may be disposed at the left edge of one VCSEL 610V, the present invention is not limited thereto, and the first region R1 may be disposed at the right edge of one VCSEL 610V, or the first region R1 may be disposed at the left edge and the right edge of one VCSEL 610V. As described above, the angle of view of the surface illumination pattern emitted from the first region R1 may be expanded by controlling the diameters of the microlenses included in the microlens array disposed in the first region R1 or the surface roughness of the etched surface. Therefore, even when the area of the first region R1 is smaller than that of the second region R2, the surface illumination pattern emitted from the first region R1 may be radiated to the entire irradiation area including the object.

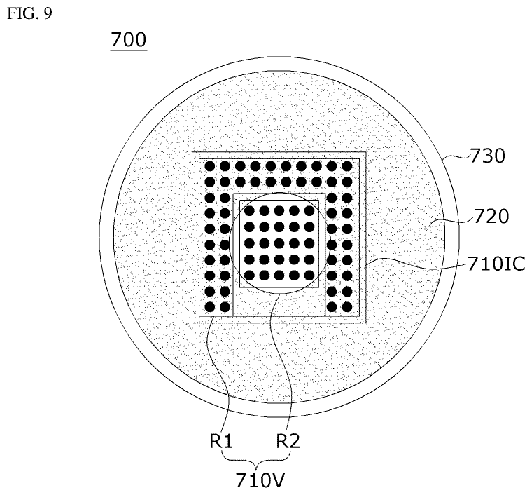

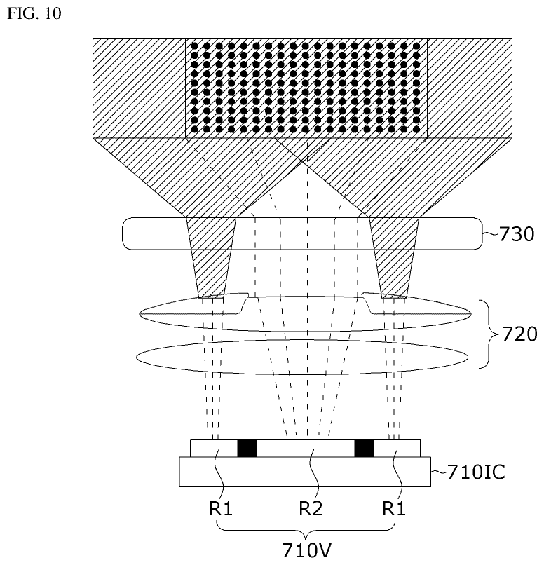

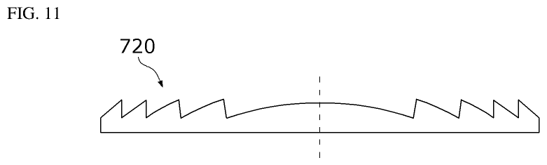

FIG. 9 is a top view of a light output device according to still another embodiment of the present invention, FIG. 10 is a cross-sectional view of the light output device according to still another embodiment of the present invention, and FIG. 11 is an example of an upper surface of a lens of the light output device according to still another embodiment of the present invention. In this specification, the light output device may be used interchangeably with the light emitting unit. The description of the light emitting portion described with reference to FIGS. 1 to 8 may be applied to the light output device, and for the convenience of explanation, duplicate descriptions of the same content are omitted.

Referring to FIGS. 9 to 11, a light output device 700 may include a light source 710, a lens group 720 disposed above the light source 710, and a cover member 730 disposed above the lens group 720.

The light source 710 may be a vertical cavity surface emitting laser (VCSEL). A VCSEL is one type of laser diode that may convert an electrical signal into an optical signal and output a wavelength of about 800 to 1000 nm, for example, about 850 nm or about 940 nm.

According to the embodiment of the present invention, the light source 710 may include a plurality of emitters in an array form and include one VCSEL 710V including a first region R1 and a second region R2 that are isolated from each other, and the first region R1 and the second region R2 may be independently driven by one driving integrated chip (IC) 710IC. That is, each of the first region R1 and the second region R2 may have an array form including a plurality of emitters, may be spaced apart from each other, may be implemented on one driving IC 710IC, and may be independently driven by one driving IC 710IC. In this case, a separation distance between the first region R1 and the second region R2 may be 10 μm to 100 μm, preferably 20 μm to 80 μm, and more preferably 30 μm to 60 μm. Accordingly, the size of the light output device 700 may be reduced while the first region R1 and the second region R2 are isolated from each other. When the first region R1 and the second region R2 are independently driven by one driving IC 710IC, fast switching is possible.

According to the embodiment of the present invention, the lens group 720 may be commonly disposed on the first region R1 and the second region R2. That is, as illustrated in FIG. 9, at least one lens included in the lens group 720 may be disposed to cover both the first region R1 and the second region R2. Accordingly, an alignment process between the light source 710 and the lens group 720 may be simplified, the size of the light output device 700 may be minimized, and the structure may be simplified.

According to the embodiment of the present invention, a diffractive optical element (DOE) pattern may be formed along an upper surface edge of the lens group 720. In this case, the DOE pattern may be formed symmetrically with respect to a center of one VCSEL 710V. According to the embodiment of the present invention, the second region R2 may be disposed in a region including the center of one VCSEL 710V, and the first region R1 may be disposed to surround at least a portion of the second region R2. An output light signal output from the first region R1 may pass through a region of an upper surface of the lens group 720 where the DOE pattern is formed, and an output light signal emitted from the second region R2 may pass through a region of the upper surface of the lens group 720 where the DOE pattern is not formed. Accordingly, the output light signal output from the first region R1 may be emitted in a surface illumination pattern, and the output light signal output from the second region R2 may be emitted in a point illumination pattern. Accordingly, a camera device capable of extracting depth information with high precision not only at a short distance but also at a long distance may be obtained. Alternatively, a camera device capable of performing depth information extraction according to the ToF method as well as depth information extraction according to the IR structured light method may be obtained. Particularly, when the output light signal passes through the DOE pattern, an enlarged field of view may be provided. Accordingly, when the second region R2 is disposed in the region including the center of one VCSEL 710V and the first region R1 is disposed to surround at least a portion of the second region R2, an irradiation region of the surface illumination pattern and an irradiation region of the point illumination pattern may overlap.

In the above description, the embodiment of FIGS. 4 to 8 and the embodiment of FIGS. 9 to 11 are described as independent embodiments, but are not limited thereto. The embodiment of FIGS. 4 to 8 and the embodiment of FIGS. 9 to 11 may be combined with each other. For example, in the embodiment of FIGS. 4 to 8, a DOE pattern may be formed in a region of an upper surface of the lens group 620 through which the output light signal output from the first region R1 passes. Alternatively, in the embodiment of FIGS. 9 to 11, a light conversion member may be further disposed on the first region R1 to defocus or scatter the output light signal output from the first region R1.

The camera device 1000 according to the embodiment of the present invention may be a ToF camera device that outputs a surface illumination pattern and a point illumination pattern. Accordingly, an output of the surface illumination pattern and the point illumination pattern may be adjusted depending on a distance of the object.

The camera device 1000 according to the embodiment of the present invention may be a camera device that supports both the ToF method and the IR structured light method. Accordingly, in the environment such as a dark room without background light or when precise depth information extraction is required, the camera device 1000 may output a point illumination pattern, and in the environment with background light or when the approximate location of an object is required, the camera device 1000 may output a surface illumination pattern.

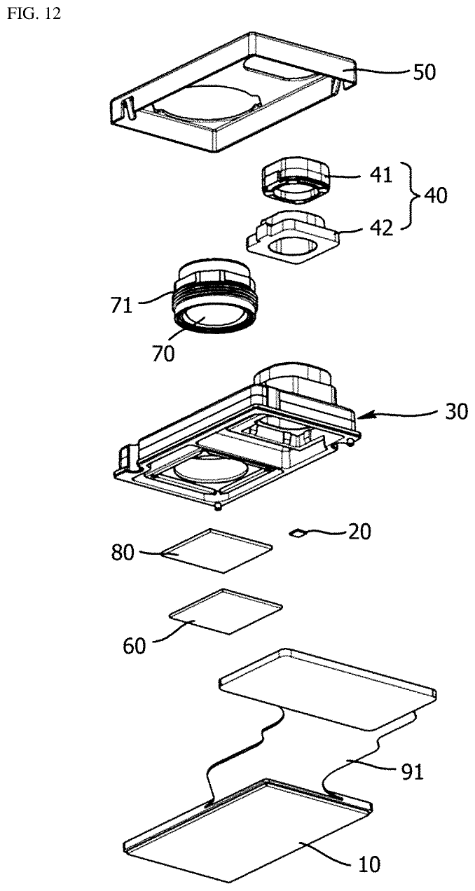

FIG. 12 is an exploded view of a camera device according to an embodiment of the present invention.

The camera device may include a light emitting unit and a light receiving unit. However, since the components such as a board 10, a holder 30, a shield can 50, or the like are formed as one piece and are commonly used for the light emitting unit and the light receiving unit, it may be difficult to distinguish between the light emitting unit and the light receiving unit. In this case, each of the above components may be understood to be a component of each of the light emitting unit and the light receiving unit. However, as a modified example, common components such as the board 10, the holder 30, the shield can 50, and the like may be provided separately for the light emitting unit and the light receiving unit.

The light emitting unit may include the board 10, a light source 20, the holder 30, a diffusion member 41, a diffuser ring 42, and the shield can 50. The light receiving unit may include the board 10, a sensor 60, a filter 80, the holder 30, a lens 70, a barrel 71, and the shield can 50.

The board 10 may include a printed circuit board (PCB). The board 10 may be connected to a connector through an FPCB 91. The board 10 and the FPCB 91 may be formed as a rigid flexible PCB (RFPCB). The light source 20 and the sensor 60 may be disposed on the board 10. The board 10 may be disposed under the holder 30. The board 10 may include a terminal. The terminal of the board 10 may be coupled to a coupling portion of the shield can 50. The terminal of the board 10 may include a plurality of terminals. The terminals of the board 10 may include two terminals.

The light source 20 may be disposed on the board 10. The light source 20 may be disposed in contact with the board 10. The light source 20 may be disposed above the board 10. The light source 20 may be disposed on the board 10. The light source 20 may correspond to the light source 110, 610, or 710 described above.

The holder 30 may be disposed above the board 10. The holder 30 may be disposed in contact with the board 10. The holder 30 may be disposed above the board 10. The holder 30 may be disposed on the board 10. The holder 30 may be fixed to the board 10 by an adhesive. The holder 30 may accommodate the light source 20, a diffuser module 40, the sensor 60, and the filter 80 therein. The holder 30 may be a plastic injection molded product. The holder 30 may be formed by injection molding.

The diffuser module 40 may include the diffusion member 41 and the diffuser ring 42. The diffuser module 40 may be formed integrally as in the modified example, but in the present embodiment, it may be manufactured separately as the diffusion member 41 and the diffuser ring 42 to increase moldability during injection molding. The diffusion member 41 and the diffuser ring 42 may be separated from each other.

The diffusion member 41 may be a diffuser lens. The diffusion member 41 may correspond to the lens group 120 described above. The diffusion member 41 may be disposed in the holder 30. The diffusion member 41 may be coupled to the holder 30. The diffusion member 41 may be fixed to the holder 30. The diffusion member 41 may be disposed on an optical path of light emitted from the light source 20. The diffusion member 41 may be disposed on the light source 20. The diffusion member 41 may be disposed above the light source 20. The diffusion member 41 may be a plastic injection molded product. The diffusion member 41 may be formed by plastic injection molding. A height of an upper end of the diffusion member 41 may correspond to a height of an upper end of the lens 70. The diffusion member 41 may be inserted upward in a vertical direction and coupled to the holder 30. In this case, the upward direction may be a direction from a lower part of the holder 30 toward an upper part of the holder 30. A portion of the diffusion member 41 may overlap the holder 30 in the upward direction.

The diffuser ring 42 may be disposed in the holder 30. The diffuser ring 42 may be fixed to the holder 30. The diffuser ring 42 may be coupled to the holder 30. The diffuser ring 42 may be disposed under the diffusion member 41. The diffuser ring 42 may support the diffusion member 41. The diffuser ring 42 may be in contact with the diffusion member 41. The diffuser ring 42 may be a plastic injection molded product. The diffuser ring 42 may be formed by plastic injection molding.

The shield can 50 may cover a body of the holder 30. The shield can 50 may include a cover. The shield can 50 may include a cover can. The shield can 50 may be a non-magnetic part. The shield can 50 may be formed of a metal material. The shield can 50 may be formed of a metal plate. The shield can 50 may be electrically connected to the board 10. The shield can 50 may be connected to the board 10 through a solder ball. Through this, the shield can 50 may be grounded. The shield can 50 may block electromagnetic interference (EMI). In this case, the shield can 50 may be called an ‘EMI shield can.’ In the present embodiment, as a high voltage is used inside the optical device, electronic interference noise may increase, and the shield can 50 may block the electronic interference noise.

The sensor 60 may be disposed on the board 10. The sensor 60 may be disposed on the other side of a partition wall of the holder 30 on the board 10. That is, the sensor 60 may be disposed on a side opposite to the light source 20 based on the partition wall of the holder 30. The sensor 60 may detect infrared light. The sensor 60 may detect light of a specific wavelength among infrared light. The sensor 60 may detect light passing through the filter 80. The sensor 60 may detect light in the wavelength band of the light source 20. Through this, the sensor 60 may detect light emitted from the light source 20 and reflected by a subject, thereby sensing 3D image information of the subject. Although an effective sensing region of the sensor 60 is disposed to correspond to the diffusion member 41, the sensor 60 may be disposed so as to be biased toward the partition wall as a whole. A circuit pattern or the like of the sensor 60 may be disposed in a portion of the sensor 60 that is biased toward the partition wall.

The lens 70 may be fixed in the barrel 71. The lens 70 may be a plastic injection molded product. The lens 70 may be formed by plastic injection molding. The lens 70 may include a plurality of lenses.

The filter 80 may be disposed between the lens 70 and the sensor 60. The filter 80 may be a band pass filter through which light of a specific wavelength passes. Infrared light may pass through the filter 80. Light of a specific wavelength among infrared light may pass through the filter 80. Light in the wavelength band of light emitted by the light source 20 may pass through the filter 80. The filter 80 may block visible light. The filter 80 may be coupled to the holder 30. A groove having a size corresponding to that of the filter 80 may be formed in the holder 30, and the filter 80 may be inserted into the groove and fixed with an adhesive. An adhesive injection groove for injecting an adhesive between the filter 80 and the holder 30 may also be formed in the groove of the holder 30. The filter 80 may be disposed at a position lower than a position of the diffuser ring 42.

Although a camera device that extracts depth information using the ToF method is mainly described in the above description, the embodiment of the present invention is not limited thereto. The camera device according to the embodiment of the present invention may mean a camera device that extracts depth information using the structured light method. That is, the camera device according to the embodiment of the present invention may use structured light having a predetermined pattern as an output light signal and generate depth information by using the disparity of the structured light. Additionally, the camera device according to the embodiment of the present invention may mean a camera device mounted in a vehicle and configured to measure a distance between the vehicle and an object. That is, the camera device according to the embodiment of the present invention may be a light detection and ranging (LiDAR) camera.

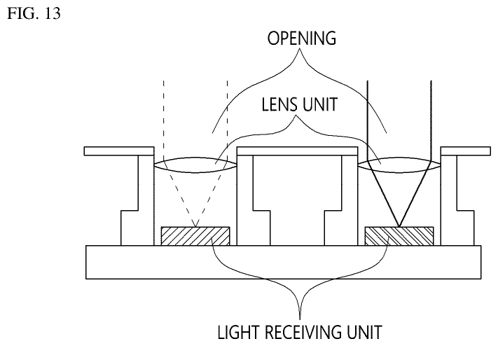

FIG. 13 is a cross-sectional view of a conventional sensor module.

Referring to FIG. 13, the conventional sensor module may include a plurality of openings, a plurality of lens units, and a plurality of light receiving units.

The conventional sensor module may require each optical system for a plurality of light receiving units to receive visible light and infrared light. The plurality of light receiving units may each receive incident light incident through separate openings and lens units. Since the conventional sensor module includes the plurality of openings and the plurality of lens units, a surface of a display may include a plurality of holes. When the surface of the display includes a plurality of holes, there may be a problem in that an area of a screen that can be displayed on the display becomes narrow.

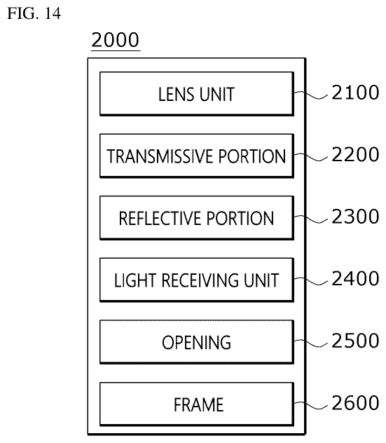

FIG. 14 is a configuration diagram of a sensor module according to an embodiment.

Referring to FIG. 14, a sensor module 2000 according to the embodiment may include a lens unit 2100, a transmissive portion 2200, a reflective portion 2300, a light receiving unit 2400, an opening 2500, and a frame 2600.

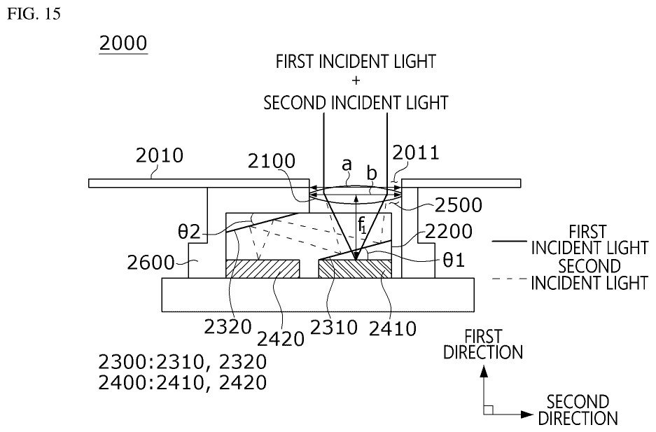

FIG. 15 is a cross-sectional view of the sensor module according to the embodiment.

Referring to FIGS. 14 and 15, the sensor module 2000 according to the embodiment may include the lens unit 2100 that refracts incident light to output first incident light and second incident light having different wavelengths, the transmissive portion 2200 that transmits the first incident light and the second incident light, the reflective portion 2300 which is disposed in the transmissive portion 2200, transmits the first incident light, and reflects the second incident light, a first light receiving unit 2410 that receives the first incident light, and a second light receiving unit 2420 that receives the second incident light, and the second incident light may be reflected by the reflective portion 2300 and reach the second light receiving unit 2420.

The sensor module 2000 may be disposed at the bottom of a display 2010. The sensor module 2000 may be disposed at the bottom of the display 2010 and may be disposed inside a device including the sensor module 2000. The sensor module 2000 may sense incident light incident through a hole 2011 of the display 2010. The sensor module 2000 may be disposed below the hole 2011 of the display 2010.

The first incident light and the second incident light may be incident light incident on the sensor module 2000 according to the embodiment. Here, the first incident light may correspond to the visible light range, and the second incident light may correspond to the infrared (IR) range. That is, the first incident light and the second incident light correspond to light with different broadbands, and may be light corresponding to the result of incident light being filtered by different media.

The first incident light and the second incident light may have different wavelengths. Incident light may be incident on the sensor module 2000 through a single hole 2011 and the opening 2500 and pass through the lens unit 2100. The incident light may be separated into the first incident light and the second incident light by passing through the lens unit 2100. The first incident light may be recognized by being incident on the first light receiving unit 2410 after passing through the lens unit 2100. The second incident light may be recognized by being incident on the second light receiving unit 2420 after passing through the lens unit 2100. The first incident light may include visible light. The second incident light may include infrared light. That is, the incident light may be divided into the first incident light and the second incident light by passing through the lens unit 2100.

The sensor module 2000 according to the embodiment may include the lens unit 2100 that refracts incident light to output the first incident light and the second incident light having different wavelengths.

The lens unit 2100 may refract the first incident light and the second incident light. The lens unit 2100 may refract incident light passing through the hole 2011 and the opening 2500 of the display 2010. The lens unit 2100 may refract incident light and allow the incident light to reach the light receiving unit 2400. The lens unit 2100 may focus incident light into one focus. The lens unit 2100 may include a convex lens that focuses incident light into one point. The lens unit 2100 may have a predetermined focal length. The lens unit 2100 may focus incident light on a predetermined focal length. A focal length of the lens unit 2100 may vary depending on a wavelength of incident light. A focal length of the first incident light of the lens unit 2100 and a focal length of the second incident light of the lens unit 2100 may be different. The first incident light may be collected at the first light receiving unit 2410 after passing through the lens unit 2100. The second incident light may be collected at the second light receiving unit 2420 after passing through the lens unit 2100.

The lens unit 2100 according to the embodiment may refract the first incident light to be focused on the first light receiving unit 2410 and refract the second incident light to be focused on the second light receiving unit 2420.

The lens unit 2100 may focus the first incident light on the first light receiving unit 2410.

According to the embodiment, the lens unit 2100 may be disposed in the opening 2500.

The lens unit 2100 may be disposed in the opening 2500. The lens unit 2100 may be disposed in the opening 2500 and refract incident light that passes through the opening 2500 and enters the sensor module 2000. The lens unit 2100 may be disposed parallel to the opening 2500 or the first light receiving unit 2410 on the same axis. The lens unit 2100 may be disposed a certain distance apart from the first light receiving unit 2410 on the same axis.

The sensor module 2000 according to the embodiment may include the transmissive portion 2200 that transmits the first incident light and the second incident light.

The transmissive portion 2200 may transmit the first incident light and the second incident light. The transmissive portion 2200 may transmit the first incident light and the second incident light refracted through the lens unit 2100. The first incident light and the second incident light passing through the lens unit 2100 may pass through the transmissive portion 2200. The transmissive portion 2200 may include a material that transmits light. The transmissive portion 2200 may include a prism. The transmissive portion 2200 may be disposed in the frame 2600 of the sensor module 2000. A shape of the transmissive portion 2200 is not limited. For example, the transmissive portion 2200 may include a cylindrical shape or a polygonal cylindrical shape. The transmissive portion 2200 may include the reflective portion 2300. The reflective portion 2300 may be disposed inside the transmissive portion 2200.

According to the embodiment, the transmissive portion 2200 may be disposed between the lens unit 2100 and the first light receiving unit 2410 and the second light receiving unit 2420.

The transmissive portion 2200 may be disposed at the bottom of the lens unit 2100. The transmissive portion 2200 may be disposed at the bottom of the lens unit 2100 and spaced a certain distance apart from the lens unit 2100. The transmissive portion 2200 may be disposed on the top of the first light receiving unit 2410 and the second light receiving unit 2420. The transmissive portion 2200 may be disposed on the top of the first light receiving unit 2410 and the second light receiving unit 2420 and spaced a certain distance apart from the first light receiving unit 2410 and the second light receiving unit 2420. Additionally, the transmissive portion 2200 may be disposed in contact with upper surfaces of the first light receiving unit 2410 and the second light receiving unit 2420. The transmissive portion 2200 may be disposed between the lens unit 2100 and the first light receiving unit 2410 and the second light receiving unit 2420 so that incident light is transmitted through the transmissive portion 2200.

The sensor module 2000 according to the embodiment may include the reflective portion 2300 which is disposed in the transmissive portion 2200, transmits the first incident light, and reflects the second incident light.

The reflective portion 2300 may transmit the first incident light and reflect the second incident light. The reflective portion 2300 may reflect incident light having a wavelength of a specific range depending on a wavelength of the incident light. The reflective portion 2300 may transmit incident light of a visible light wavelength range and reflect incident light of an infrared wavelength range. The reflective portion 2300 may be disposed in the transmissive portion 2200. The reflective portion 2300 may be disposed inside the transmissive portion 2200 and transmit or reflect incident light passing through the transmissive portion 2200. The reflective portion 2300 may include a dichroic filter.

The reflective portion 2300 according to the embodiment may be formed in a manner in which a reflection material is coated or attached in the transmissive portion 2200.

The reflective portion 2300 may be formed in the form of a thin film or plate by coating or attaching a reflective material in the transmissive portion 2200.

The reflective portion 2300 according to the embodiment may be disposed to reflect the second incident light and allow the second incident light to reach the second light receiving unit 2420.

The second incident light may be reflected by the reflective portion 2300 and reach the second light receiving unit 2420.

The second light receiving unit 2420 may not be disposed on the same axis as the opening 2500 through which the light signal is incident. Since the second incident light needs to reach the second light receiving unit 2420 to be recognized, the reflective portion 2300 may change a path by reflecting the second incident light so that it reaches the second light receiving unit 2420.

The reflective portion 2300 according to the embodiment may include a first reflective surface 2310 and a second reflective surface 2320, and the first reflective surface 2310 and the second reflective surface 2320 may be disposed parallel to each other so as to face each other.

The reflective portion 2300 may include the first reflective surface 2310 and the second reflective surface 2320. The first reflective surface 2310 and the second reflective surface 2320 may be reflective surfaces that are disposed spaced apart from each other. The first reflective surface 2310 may reflect a second optical signal refracted through the lens unit 2100. The second reflective surface 2320 may reflect the second optical signal reflected by the first reflective surface 2320 again. The second optical signal reflected by the second reflective surface 2320 may be incident on the second light receiving unit 2420. The first reflective surface 2310 and the second reflective surface 2320 may be disposed parallel to each other so as to face each other. The first reflective surface 2310 and the second reflective surface 2320 may be disposed parallel to each other so as to face each other so that the second incident light is received by the second light receiving unit 2420 parallel to the incident path after being reflected by the first reflective surface 2310 and the second reflective surface 2320.

According to the embodiment, the first reflective surface 2310 may be disposed between the lens unit 2100 and the first light receiving unit 2410 to have a predetermined angle with respect to a second direction.

The first reflective surface 2310 may be disposed between the lens unit 2100 and the first light receiving unit 2410. The first reflective surface 2310 may be disposed on the same axis between the lens unit 2100 and the first light receiving unit 2420. A center of the first reflective surface 2310 may be disposed on the same axis as a center of the lens unit 2100 and a center of the first light receiving unit 2410. The first reflective surface 2310 may be disposed spaced a certain distance apart from the lens unit 2100 or the first light receiving unit 2410. The first reflective surface 2310 may be disposed spaced a certain distance apart from the lens unit 2100 or the first light receiving unit 2410 in a first direction. The first direction may be a direction in which the first incident light is incident. The first reflective surface 2310 may be disposed between the lens unit 2100 and the first light receiving unit 2410 and reflect the second incident light refracted by the lens unit 2100. The first reflective surface 2310 may be disposed to have a predetermined angle with respect to the second direction. The second direction may be a direction perpendicular to the first direction. The first reflective surface 2310 may be disposed to have a predetermined angle with respect to the second direction so as to reflect the second incident light. For example, the first reflective surface 2310 may be disposed to have an angle of θ1 with respect to the second direction. The first reflective surface 2310 may be disposed to have a predetermined angle with respect to the second direction so as to reflect the second incident light to the second reflective surface 2320. The first reflective surface 2310 may be disposed parallel to the second reflective surface 2320.

The second reflective surface 2320 according to the embodiment may be spaced apart from the second light receiving unit 2420 in the first direction and may be disposed to have a predetermined angle with respect to the second direction.

The second reflective surface 2320 may be disposed spaced apart from the second light receiving unit 2420 in the first direction. A center of the second reflective surface 2320 may be disposed on the same axis as a center of the second light receiving unit 2420. The center of the second reflective surface 2320 and the center of the second light receiving unit 2420 may be disposed spaced apart from each other in the first direction on the same axis. The second reflective surface 2320 may be disposed spaced apart from the second light receiving unit 2420 in the first direction so that the reflected second incident light reaches the second light receiving unit 2420. The second reflective surface 2320 may be disposed to have a predetermined angle with respect to the second direction. The second reflective surface 2320 may be disposed to have a predetermined angle with respect to the second direction so as to reflect the second incident light. For example, the second reflective surface 2320 may be disposed to have an angle of θ2 with respect to the second direction. θ2 may be the same as θ1. The second reflective surface 2320 may be disposed to have a predetermined angle with respect to the second direction so as to reflect the second incident light to the second light receiving unit 2420.

The first reflective surface 2310 and the second reflective surface 2320 according to the embodiment may be disposed to have an angle greater than 0° and less than or equal to 45° with respect to the second direction.

The angle θ1 of the first reflective surface 2310 with respect to the second direction and the angle θ2 of the second reflective surface 2310 with respect to the second direction may be disposed to have an angle greater than 0° and less than or equal to 45° with respect to the second direction. The first reflective surface 2310 and the second reflective surface 2320 may be disposed to have an angle greater than 0° and less than or equal to 45° with respect to the second direction so as to reduce the thickness of the transmissive portion 2200 where the first reflective surface 2310 and the second reflective surface 2320 are disposed. The total thickness required for arranging the sensor module 2000 may be reduced by reducing the thickness of the transmissive portion 2200. Preferably, the first reflective surface 2310 and the second reflective surface 2320 may be disposed to have an angle of 25° to 35° with respect to the second direction.

The angle θ1 of the first reflective surface 2310 with respect to the second direction and the angle θ2 of the second reflective surface 2310 with respect to the second direction may be disposed to have an angle of 25° to 35° with respect to the second direction. The first reflective surface 2310 and the second reflective surface 2320 may be disposed to have an angle of 25° to 35° with respect to the second direction so as to reduce the thickness of the transmissive portion 2200 where the first reflective surface 2310 and the second reflective surface 2320 are disposed. The total thickness required for arranging the sensor module 2000 may be reduced by reducing the thickness of the transmissive portion 2200.

The sensor module 2000 according to the embodiment may include the first light receiving unit 2410 that receives the first incident light and the second light receiving unit 2420 that receives the second incident light.

The light receiving unit 2400 may receive and sense incident light. The light receiving unit 2400 may include the first light receiving unit 2410 and the second light receiving unit 2420. The first light receiving unit 2410 may receive the first incident light, and the second light receiving unit 2420 may receive the second incident light. The first light receiving unit 2410 may include a visible light recognition sensor (RGB Rx). The second light receiving unit 2420 may include an infrared recognition sensor (IR Rx). The light receiving unit 2400 may be disposed in the frame 2600 of the sensor module 2000. The light receiving unit 2400 may be disposed toward a direction in which incident light is incident.

The first light receiving unit 2410 according to the embodiment may be disposed spaced apart from the lens unit 2100 on the same axis in the first direction in which the first incident light is incident.

The first light receiving unit 2410 may be disposed spaced a certain distance apart from the lens unit 2100 on the same axis in the first direction. The first light receiving unit 2410 may be disposed spaced a focal length f1 of the lens unit 2100 apart from the lens unit 2100 in the first direction. The focal length f1 may be a focal length at which the first incident light is gathered after passing through the lens unit 2100. The first light receiving unit 2410 may sense the first incident light and thus be disposed at a focal length where the first incident light is gathered. Since the first incident light is transmitted without being reflected through the reflective portion 2300, the first light receiving unit 2410 may be disposed on the same axis as the lens unit 2100. The first light receiving unit 2410 may be disposed spaced apart in the first direction on the same axis as the lens unit 2100, the opening 2500, or the first reflective surface 2310.

The first light receiving unit 2410 and the second light receiving unit 2420 according to the embodiment may be disposed spaced apart from and parallel to each other in the second direction perpendicular to the first direction.

The second light receiving unit 2420 may be disposed spaced apart from and parallel to the first light receiving unit 2410 in the second direction. The second light receiving unit 2420 may be disposed spaced apart from the first light receiving unit 2410 in the second direction on the same axis. The second light receiving unit 2420 and the first light receiving unit 2410 may be disposed spaced the same distance apart from the transmissive portion 2200 in the first direction. The second light receiving unit 2420 may sense the second incident light and thus be disposed on a focus point where the second incident light is gathered. The second light receiving unit 2420 may be disposed on a focal point where the second incident light reflected by the first reflective surface 2310 and the second reflective surface 2320 after being refracted by the lens unit 2100 is gathered. The second light receiving unit 2420 may be disposed spaced a certain distance apart from the second reflective surface 2320 on the same axis. The second light receiving unit 2420 may be disposed spaced apart from the second reflective surface 2320 in the first direction on the same axis. The second light receiving unit 2420 may be disposed on the same axis as the second reflective surface 2320 and may sense the second incident light reflected by the second reflective surface 2320.

The sensor module 2000 according to the embodiment may include the opening 2500 that allows the first incident light and the second incident light to enter the lens unit 2100, and include the frame 2600 that accommodates the lens unit 2100, the transmissive portion 2200, the reflective portion 2300, and the first and second light receiving units 410 and 42.

The opening 2500 may allow the first incident light and the second incident light to enter the lens unit 2100. The opening 2500 may be disposed in the frame 2600 of the sensor module 2000. The opening 2500 may include an opening shape passing through a portion of one surface of the frame 2600. The opening 2500 may allow incident light from the outside to enter the inside of the sensor module. The opening 2500 may allow incident light passing through the hole 2011 of the display 2010 to enter the inside of the sensor module. The opening 2500 may be disposed below the hole 2011. The opening 2500 may be disposed below the hole 2011 so that incident light passing through the hole 2011 enters the sensor module 2000. The lens unit 2100 may be disposed inside the opening 2500. The lens unit 2100 may be disposed inside the opening 2500 to refract incident light passing through the opening 2500. The lens unit 2100 may be disposed inside the opening 2500 in a direction parallel to the opening 2500. Since the sensor module 2000 according to the embodiment may include a single opening 2500 and the first incident light and the second incident light are incident through the single opening 2500, the sensor module 2000 may include a single hole 2011 in the surface of the display 2010 disposed on the sensor module. The single hole 2011 may be included in the surface of the display 2010, thereby increasing an area of a region of the display 2010 where a screen is displayed and improving the performance of the display 2010.

The opening 2500 according to the embodiment may be disposed spaced apart in the first direction on the same axis as the first light receiving unit 2410.

The opening 2500 may be disposed spaced apart from the first light receiving unit 2410 in the first direction on the same axis. The opening 2500 and the first light receiving unit 2410 may be disposed on the same axis as a direction of incidence of incident light, and thus the incident light may pass through the opening 2500, and the passed incident light may reach the first light receiving unit 2410.

A width a of the opening 2500 in the second direction according to the embodiment may be 1 time or more and 2 times or less a width b of the lens unit 2100 in the second direction.

The width a of the opening 2500 in the second direction may be 1 time or more and 2 times or less the width b of the lens unit 2100 in the second direction. Since the lens unit 2100 is disposed inside the opening 2500 and the opening 2500 and the lens unit 2100 may be disposed parallel to the second direction, the width a of the opening 2500 in the second direction may be greater than or equal to the width b of the lens unit 2100 in the second direction. In addition, the width a of the opening 2500 in the second direction may be formed to be twice or less the width b of the lens unit 2100 in the second direction so that the opening 2500 with a narrower width is formed than when there are two or more lens units and openings. Preferably, the width a of the opening 2500 in the second direction may be the same as the width b of the lens unit 2100 in the second direction. An area of the hole 2011 required in the surface of the display 2010 by forming a narrow opening 2500 may be narrowed, thereby improving the performance of the display 2010.

The sensor module 2000 according to the embodiment may include the frame 2600 that accommodates the lens unit 2100, the transmissive portion 2200, the reflective portion 2300, the first light receiving unit 2410, and the second light receiving unit 2420.

The frame 2600 may accommodate the lens unit 2100, the transmissive portion 2200, the reflective portion 2300, the first light receiving unit 2410, and the second light receiving unit 2420. The frame 2600 may be disposed to surround the transmissive portion 2200, the first light receiving unit 2410, and the second light receiving unit 2420 so as to protect the transmissive portion 2200, the first light receiving unit 2410, and the second light receiving unit 2420. The frame 2600 may be disposed to surround the transmissive portion 2200, the first light receiving unit 2410, and the second light receiving unit 2420 to maintain a shape of the sensor module 2000. The frame 2600 may be disposed in contact with the display 2010. At least a portion of one surface of the frame 2600 may include the opening 2500.

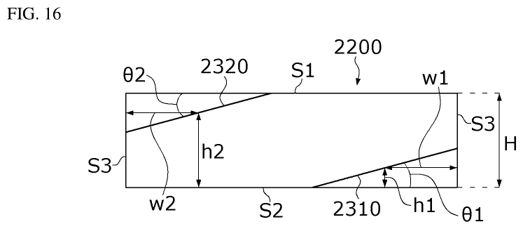

FIG. 16 is a cross-sectional view of a transmissive portion of the sensor module according to the embodiment.

Referring to FIGS. 15 and 16, the transmissive portion 2200 of the sensor module 2000 according to the embodiment may include a first surface S1, a second surface S2 facing the first surface S1, and a third surface S3 disposed between the first surface S1 and the second surface S2, in which the first surface S1 and the second surface S2 are parallel to the lens unit 2100 or the first light receiving unit 2410, and the third surface S3 may be perpendicular to the first surface S1 and the second surface S2.

The first surface S1 may be an upper surface of the transmissive portion 2200. The first surface S1 may be a surface facing the lens unit 2100 or the opening 2500 of the transmissive portion 2200. The first surface S1 may face the second surface S2 while being parallel thereto. The first surface S1 may be perpendicular to the third surface S3. Incident light may be incident on the transmissive portion 2200 through the first surface S1. The first surface S1 and the second reflective surface 2320 may form a predetermined angle θ2.

The second surface S2 may be a lower surface of the transmissive portion 2200. The second surface S2 may be a surface facing the first light receiving unit 2410 or the second light receiving unit 2420 of the transmissive portion 2200. The second surface S2 may face the first surface S2 while being parallel thereto. The second surface S2 may be perpendicular to the third surface S3. Incident light may be emitted from the transmissive portion 2200 through the second surface S2. The second surface S2 and the first reflective surface 2310 may form a predetermined angle θ1. The second surface S2 may be in contact with the first light receiving unit 2410 or the second light receiving unit 2420.

The third surface S3 may be a side surface of the transmissive portion 2200. The third surface S3 may be perpendicular to the first surface S1 or the second surface S2. The third surface S3 may have a predetermined height H in the first direction.

A sum of a vertical distance h1 between one point on the first reflective surface 2310 and the second surface S2 of the sensor module 2000 according to the embodiment and a vertical distance h2 between one point on the second reflective surface 2320 and the second surface S2 is 0.8 to 1.2 times the height H of the third surface S3 in the first direction, and one point on the first reflective surface 2310 may be at a first distance from an end of the first reflective surface 2310 in a direction toward the second reflective surface 2320, and one point on the second reflective surface 2320 may be at a first distance from an end of the second reflective surface 2320 in a direction toward the first reflective surface 2310.

The sum of the vertical distance h1 between one point on the first reflective surface 2310 and the second surface S2 and the vertical distance h2 between one point on the second reflective surface 2320 and the second surface S2 may be 0.8 to 1.2 times the height H of the third surface S3 in the first direction. One point of the first reflective surface 2310 may be at the first distance from the end of the first reflective surface 2310 in the direction toward the second reflective surface 2320, and one point of the second reflective surface 2320 may be at the first distance from the end of the second reflective surface 2320 in the direction toward the first reflective surface 2310. The one point on the first reflective surface 2310 and the one point on the second reflective surface 2320 may be points that are symmetrical with respect to a center of the transmissive portion 2200. The sum of the vertical distance h1 between one point on the first reflective surface 2310 and the second surface S2 and the vertical distance h2 between one point on the second reflective surface 2320 and the second surface S2 may be 0.8 to 1.2 times the height H of the third surface S3 in the first direction, thereby allowing the thickness of the transmissive portion 2200 to be minimized while including both the first reflective surface 2310 and the second reflective surface. Preferably, the sum of the vertical distance h1 between one point on the first reflective surface 2310 and the second surface S2 and the vertical distance h2 between one point on the second reflective surface 2320 and the second surface S2 may be the same as the height H of the third surface S3 in the first direction.

The shortest horizontal distance w1 between one point on the first reflective surface 2310 and the third surface S3 of the sensor module 2000 according to the embodiment may be 0.9 to 1.1 times the shortest horizontal distance w2 between one point on the second reflective surface 2320 and the third surface S3, and the one point on the first reflective surface 2310 may be at the first distance from the end of the first reflective surface 2310 in the direction toward the second reflective surface 2320, and the one point on the second reflective surface 2320 may be at the first distance from the end of the second reflective surface 2320 in the direction toward the first reflective surface 2310.

The shortest horizontal distance w1 between one point on the first reflective surface 2310 and the third surface S3 may be 0.9 to 1.1 times the shortest horizontal distance w2 between one point on the second reflective surface 2320 and the third surface S3. The one point of the first reflective surface 2310 may be at the first distance from the end of the first reflective surface 2310 in the direction toward the second reflective surface 2320, and the one point of the second reflective surface 2320 may be at the first distance from the end of the second reflective surface 2320 in the direction toward the first reflective surface 2310. The one point on the first reflective surface 2310 and the one point on the second reflective surface 2320 may be points that are symmetrical with respect to the center of the transmissive portion 2200. The shortest horizontal distance w1 between one point on the first reflective surface 2310 and the third surface S3 is 0.9 to 1.1 times the shortest horizontal distance w2 between one point on the second reflective surface 2320 and the third surface S3, thereby minimizing a width of the transmissive portion 2200 while including both the first reflective surface 2310 and the second reflective surface. Preferably, the shortest horizontal distance w1 between one point on the first reflective surface 2310 and the third surface S3 may be the same as the shortest horizontal distance w2 between one point on the second reflective surface 2320 and the third surface S3.

A mobile device according to an embodiment may include a display including a hole and a sensor module disposed below the display, in which the sensor module includes a lens unit that refracts incident light passing through the hole to output first incident light and second incident light having different wavelengths, a transmissive portion which transmits the first incident light and the second incident light, a reflective portion which is disposed in the transmissive portion, transmits the first incident light and reflects the second incident light, and a first light receiving unit that receives the first incident light, and a second light receiving unit that receives the second incident light, wherein the hole, the lens unit, and the first light receiving unit may overlap in an optical axis direction of the lens unit.

Although the description has been made focusing on examples above, these are merely examples and do not limit the present invention, and those with ordinary knowledge in the field to which the present invention belongs will recognize that various modifications and applications not exemplified above are possible without departing from the essential characteristics of these examples. For example, each component specifically shown in the examples may be modified and implemented. Further, the differences related to these modifications and applications should be interpreted as being included within the scope of the present invention defined in the appended claims.

1. A light output device comprising:
one vertical cavity surface emission laser (VCSEL) including a plurality of emitters in an array form and including a first region and a second region that are isolated from each other;
a lens disposed on the first region and the second region and overlapping both the first region and the second region in an optical axis direction;
a light conversion member disposed between the first region and the lens to defocus or scatter an output light signal output from the first region; and
one driving IC configured to independently drive an emitter of the first region and an emitter of the second region,
wherein the output light signal output from the first region is emitted in a surface illumination pattern, and an output light signal output from the second region is emitted in a point illumination pattern, and
the second region directly faces the lens in the optical axis direction.

2. The light output device of claim 1, wherein the light conversion member is a layer including a microlens array protruding toward the lens or an etched surface protruding toward the lens.

3. The light output device of claim 1, wherein a vertical distance between the first region and an upper surface of the light conversion member is shorter than a vertical distance between the upper surface of the light conversion member and the lens.

4. The light output device of claim 3, wherein the light conversion member is disposed to be in direct contact with the first region.

5. The light output device of claim 1, wherein the one VCSEL is disposed on a board on which the one driving IC is disposed, and
a height of the first region and a height of the second region are the same based on the board.

6. The light output device of claim 1, wherein the light conversion member is not disposed between the second region and the lens.

7. The light output device of claim 1, wherein, when viewed from above, an area of the second region is greater than an area of the first region.

8. The light output device of claim 7, wherein the second region is disposed in a region including a center of the one VCSEL, and the first region is disposed in an edge region of the one VCSEL.

9. The light output device of claim 1, wherein the second region is disposed in a region including a center of the one VCSEL, and the first region is disposed to surround at least a portion of the second region.

10. The light output device of claim 9, wherein a diffractive optical element (DOE) pattern is formed along an edge region of an upper surface of the lens.

11. The light output device of claim 9, wherein the DOE pattern is formed symmetrically with respect to a center of the one VCSEL.

12. The light output device of claim 11, wherein an output light signal output from the first region passes through a region of an upper surface of the lens where the DOE pattern is formed.

13. The light output device of claim 12, wherein an output light signal output from the second region passes through a region of the upper surface of the lens where the DOE pattern is not formed.

14. The light output device of claim 12, wherein a width of the first region in a direction perpendicular to the optical axis is greater than a width of the second region in a direction perpendicular to the optical axis.

15. A sensor module comprising:
a lens unit that refracts incident light to output first incident light and second incident light having different wavelengths,
a transmissive portion that transmits the first incident light and the second incident light,
a reflective portion which is disposed in the transmissive portion, transmits the first incident light, and reflects the second incident light, and
a first light receiving unit that receives the first incident light and a second light receiving unit that receives the second incident light, and
wherein the second incident light is reflected by the reflective portion and reach the second light receiving unit.

16. The sensor module of claim 15, wherein the first light receiving unit is disposed spaced apart from the lens unit on the same axis in a first direction in which the first incident light is incident, and the first light receiving unit and the second light receiving unit are disposed spaced apart in a second direction perpendicular to the first direction while being parallel to each other.

17. The sensor module of claim 15, wherein the lens unit refracts the first incident light to be focused on the first light receiving unit and refract the second incident light to be focused on the second light receiving unit.

18. The sensor module of claim 15, wherein the transmissive portion is disposed between the lens unit and the first light receiving unit and the second light receiving unit.

19. The sensor module of claim 15, wherein the transmissive portion has a cylindrical or polygonal cylindrical shape, and the reflective portion is formed in a manner in which a reflective material is coated or attached in the transmissive portion.

20. The sensor module of claim 16, wherein the reflective portion includes a first reflective surface and a second reflective surface, and the first reflective surface and the second reflective surface are disposed parallel to each other so as to face each other.
